(19) United States
(12) Patent Application Publication
(10) Pub. No.: US 2024/0411235 A1
(43) Pub. Date: Dec. 12, 2024

(54) SEMICONDUCTOR MANUFACTURING APPARATUS

(71) Applicant: Samsung Electronics Co., Ltd., Suwon-si (KR)

(72) Inventors: Dae Geun YOON, Suwon-si (KR); Sung Hyup Kim, Suwon-si (KR); In Jae Lee, Suwon-si (KR)

(73) Assignee: Samsung Electronics Co., Ltd., Suwon-si (KR)

(21) Appl. No.: 18/419,219

(22) Filed: Jan. 22, 2024

(30) Foreign Application Priority Data
Jun. 8, 2023 (KR) 10-2023-0073276

(51) Int. Cl. G03F 7/00; H01L 21/67; H01L 21/68; H01L 21/683

(52) U.S. Cl. CPC G03F 7/70933; G03F 7/70708; G03F 7/70716; G03F 7/70808; G03F 7/70858; H01L 21/67017; H01L 21/68; H01L 21/6831

(57) ABSTRACT

A semiconductor manufacturing apparatus includes a wafer stage, a wafer table including main body supported by the wafer stage and a protrusion protruding from a sidewall of the main body in a first direction, a position module on an upper surface of the wafer table and configured to move in the first direction and a second direction intersecting the first direction, an electrostatic chuck on an upper surface of the position module, a first cable connected to the position module, the first cable extending in the first direction and configured to move the position module in the first direction, a second cable between a bottom surface of the protrusion and a lower wall of the wafer stage, the second cable extending in the second direction and configured to move the position module in the second direction, and a cable connecting member connecting the first cable and the second cable.

### CROSS-REFERENCE TO RELATED APPLICATION

This application claims priority to Korean Patent Application No. 10-2023-0073276, filed on Jun. 8, 2023, in the Korean Intellectual Property Office, the disclosure of which is incorporated by reference herein in its entirety.

### BACKGROUND

### 1. Field

The present disclosure relates to a semiconductor manufacturing apparatus.

### 2. Description of Related Art

Photolithography may refer to the process of transferring circuit patterns onto the surface of a wafer using a mask. During the exposure of the wafer, contamination (e.g., due to contaminants such as fine particles) may occur. If such contaminants adhere to the surface of the wafer, the contaminants may cause defects in the wafer.

Therefore, contaminants should be completely or mostly removed to prevent defects in semiconductor devices.

### SUMMARY

One or more embodiment of the present disclosure provide is a semiconductor manufacturing apparatus configured to remove contaminants through an exhaust system during semiconductor manufacturing processes.

Additional aspects will be set forth in part in the description which follows and, in part, will be apparent from the description, or may be learned by practice of the presented embodiments.

According to an aspect of an example embodiment, a semiconductor manufacturing apparatus may include a wafer stage, a wafer table including main body supported by the wafer stage and a protrusion protruding from a sidewall of the main body in a first direction, a position module on an upper surface of the wafer table and configured to move in the first direction and a second direction intersecting the first direction, an electrostatic chuck on an upper surface of the position module, a first cable connected to the position module, the first cable extending in the first direction and configured to move the position module in the first direction, a second cable between a bottom surface of the protrusion and a lower wall of the wafer stage, the second cable extending in the second direction and configured to move the position module in the second direction, a cable connecting member connecting the first cable and the second cable, and a penetrating pipe extending in the first direction and penetrating a sidewall of the wafer stage, where the penetrating pipe has a circular cross-section along a plane perpendicular to the first direction.

According to an aspect of an example embodiment, a semiconductor manufacturing apparatus may include a wafer stage, a wafer table including main body supported by the wafer stage and a protrusion protruding from a sidewall of the main body in a first direction, a position module on an upper surface of the wafer table and configured to move in the first direction and a second direction intersecting the first direction, an electrostatic chuck on an upper surface of the position module, a first cable connected to the position module, the first cable extending in the first direction and configured to move the position module in the first direction, a second cable between a bottom surface of the protrusion and a lower wall of the wafer stage, the second cable extending in the second direction and configured to move the position module in the second direction, a cable connecting member connecting the first cable and the second cable, and a penetrating pipe extending in the first direction and penetrating a sidewall of the wafer stage, where the penetrating pipe may include an upper generator line having a first height from the lower wall of the wafer stage that is greatest among heights of generator lines of the penetrating pipe and a lower generator line having a second height from the lower wall of the wafer stage that is smallest among the heights of the generator lines of the penetrating pipe, and a length of the upper generator line in the first direction may be different from a length of the lower generator line in the first direction.

According to an aspect of an example embodiment, a semiconductor manufacturing apparatus may include a wafer stage, a wafer table including main body supported by the wafer stage and a protrusion protruding from a sidewall of the main body in a first direction, a position module on an upper surface of the wafer table and configured to move in the first direction and a second direction intersecting the first direction, an electrostatic chuck on an upper surface of the position module, a first cable connected to the position module, the first cable extending in the first direction and configured to move the position module in the first direction, a second cable between a bottom surface of the protrusion and a lower wall of the wafer stage, the second cable extending in the second direction and configured to move the position module in the second direction, a cable connecting member connecting the first cable and the second cable, and a penetrating pipe extending in a third direction intersecting the first direction and the second direction, the penetrating pipe penetrating the lower wall of the wafer stage, where the penetrating pipe has a circular cross-section along a plane perpendicular to the third direction.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a diagram of a lithography apparatus according to one or more embodiments of the present disclosure;

FIG. 2 is a top view of a wafer stage according to one or more embodiments of the present disclosure;

FIG. 3 is a cross-sectional view taken along line A-A of FIG. 2 according to one or more embodiments of the present disclosure;

FIG. 4 is an enlarged cross-sectional view of a region R1 of FIG. 3 according to one or more embodiments of the present disclosure;

FIG. 5 is a cross-sectional view taken along line B-B of FIG. 2 according to one or more embodiments of the present disclosure;

FIG. 6 is an enlarged cross-sectional view of a region R2 of FIG. 5 according to one or more embodiments of the present disclosure;

FIG. 7 is a perspective view taken along line C-C of FIG. 2 according to one or more embodiments of the present disclosure;

FIG. 8 is a cross-sectional view, taken along line A-A, of a wafer stage according to one or more embodiments of the present disclosure;

FIG. 9 is a cross-sectional view, taken along line A-A, of a wafer stage according to one or more embodiments of the present disclosure;

FIG. 10 is an enlarged cross-sectional view of a region R3 of FIG. 9 according to one or more embodiments of the present disclosure;

FIG. 11 is a cross-sectional view, taken along line A-A, of a wafer stage according to one or more embodiments of the present disclosure;

FIG. 12 is a cross-sectional view, taken along line A-A, of a wafer stage according to one or more embodiments of the present disclosure; and

FIG. 13 is an enlarged cross-sectional view of a region R4 of FIG. 12 according to one or more embodiments of the present disclosure.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

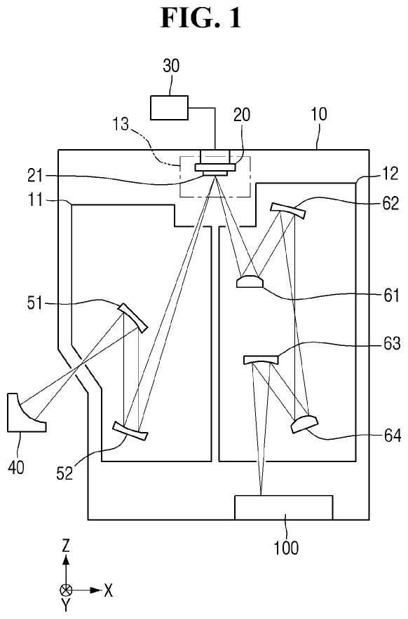

FIG. 1 is a diagram of a lithography apparatus according to one or more embodiments of the present disclosure.

Referring to FIG. 1, the lithography apparatus may include a main chamber 10, a first sub-chamber 11, a second sub-chamber 12, a reticle stage module 13, a reticle stage power source 30, a source 40, reflective mirrors 51 and 52 of an illumination optical system, reflective mirrors 61, 62, 63, and 64 of a projection optical system, and a wafer stage 100.

The main chamber 10 may include the first sub-chamber 11, the second sub-chamber 12, the reticle stage module 13, the reflective mirrors 51 and 52, the reflective mirrors 61, 62, 63, and 64, and the wafer stage 100. The interior of the main chamber 10 may be maintained in a vacuum state.

The first sub-chamber 11 may be positioned within the main chamber 10. At least one or more reflective mirrors of the illumination optical system (i.e., the reflective mirrors 51 and 52) may be arranged in the first sub-chamber 11.

Exposure light reflected from the reflective mirrors 51 and 52 may pass through the first sub-chamber 11 and then reach a reticle 21, which is fixed on the reticle stage 20. To enhance the reflection efficiency of the exposure light, the interior of the first sub-chamber 11 may be maintained in a vacuum state.

The second sub-chamber 12 may be positioned within the main chamber 10. At least one or more reflective mirrors of the projection optical system (i.e., the reflective mirrors 61, 62, 63, and 64) may be arranged in the second sub-chamber 12.

The exposure light reflected from the surface of the reticle 21 may be directed onto wafers on the wafer stage 100 after being reflected by the reflective mirrors 61, 62, 63, and 64. To enhance the reflection efficiency of the exposure light, the interior of the second sub-chamber 12 may be maintained in a vacuum state.

The reticle stage module 13 may be positioned within the main chamber 10, on top of the first and second sub-chambers 11 and 12.

The reticle stage 20 may be positioned at the top of the main chamber 10. The reticle 21 may be fixed on the reticle stage 20, which is capable of performing a scanning operation.

The reticle 21 may reflect the exposure light passing through the first sub-chamber 11 towards the second sub-chamber 12.

The reticle 21 may include first and second surfaces that face each other. The reticle 21 may include a pattern region, which is formed on the first surface of the reticle 21.

The exposure light passing through the first sub-chamber 11 may be incident on the first surface of the reticle 21 where the pattern region is formed. The pattern region may include a material capable of absorbing the exposure light generated by the source 40.

As a result, the remaining exposure light not absorbed by the pattern region on the first surface of the reticle 21 may be incident onto the reflective mirrors 61, 62, 63, and 64, which are positioned within the second sub-chamber 12.

The reticle 21 may include a first reticle conductive film, which is formed on the first surface of the reticle 21, and a second reticle conductive film, which is formed on the second surface of the reticle 21. The first surface of the reticle 21 may be defined by the first reticle conductive film, and the second surface of the reticle 21 may be defined by the second reticle conductive film.

For example, the first and second reticle conductive films may include ruthenium (Ru) and chromium nitride, but the present disclosure is not limited thereto.

In one or more embodiments, a reticle masking blade may be further provided. The reticle masking blade may be positioned between the reticle stage 20 and the first and second sub-chambers 11 and 12. The reticle masking blade may be connected to the outside of the first sub-chamber 11 and/or the second sub-chamber 12, but the present disclosure is not limited thereto.

The reticle masking blade may control the dimension of the exposure light incident on the first surface of the reticle 21.

The reticle stage power source 30 may be electrically connected to the reticle 21 and the reticle stage 20.

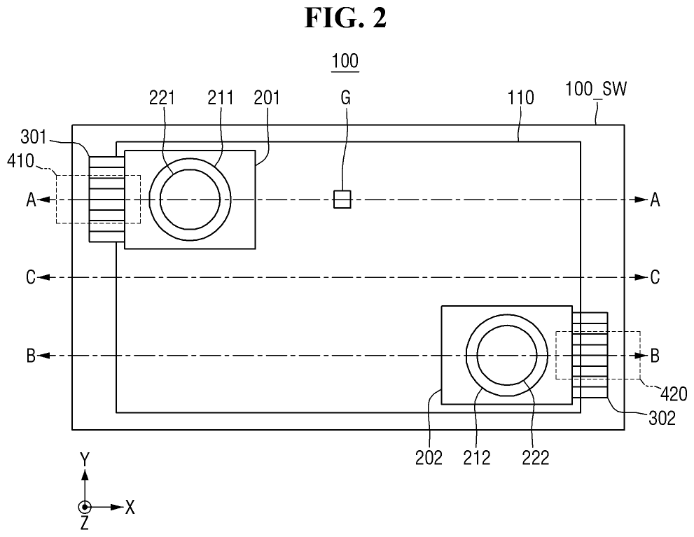

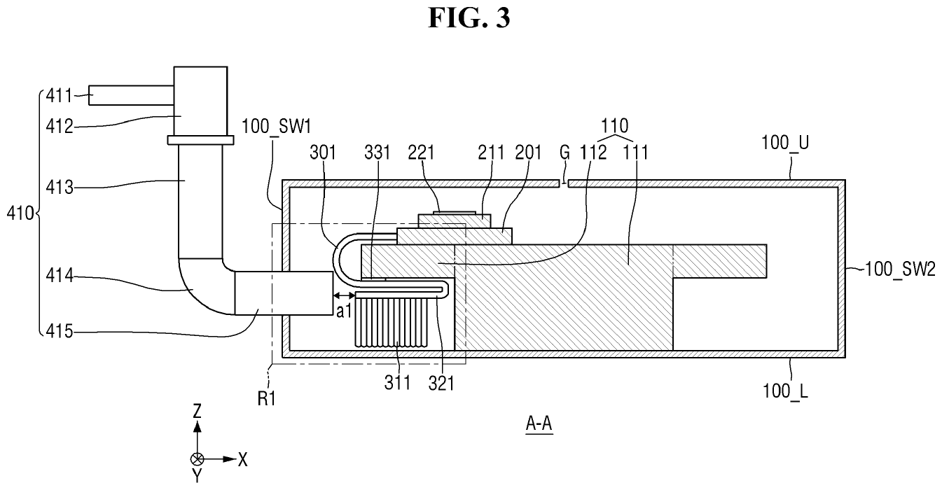

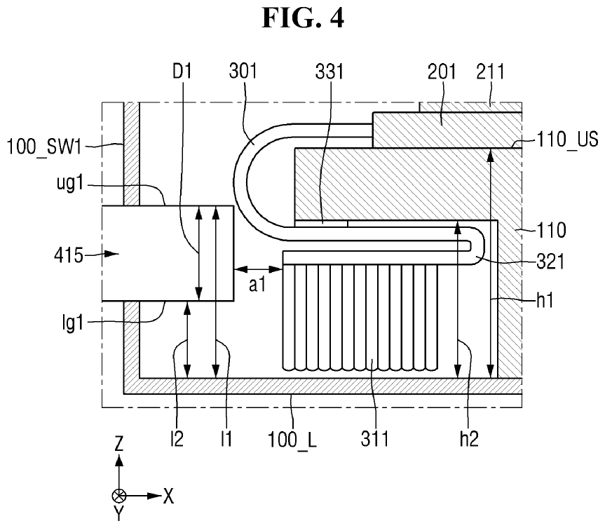

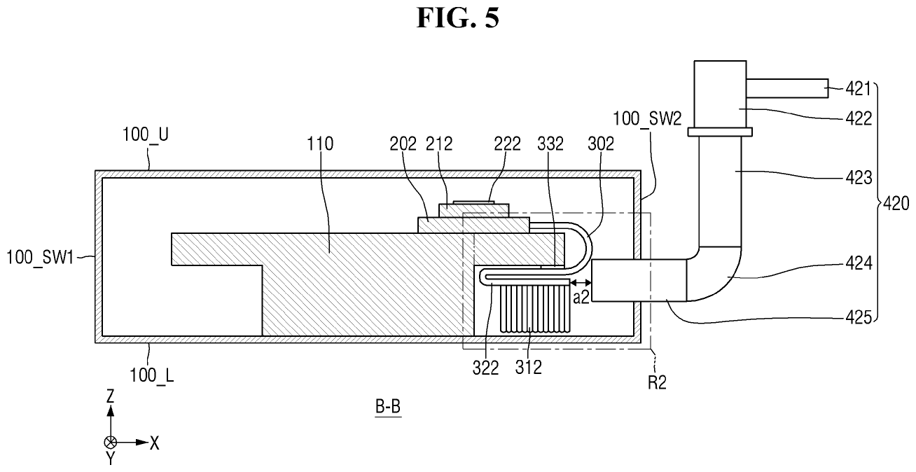

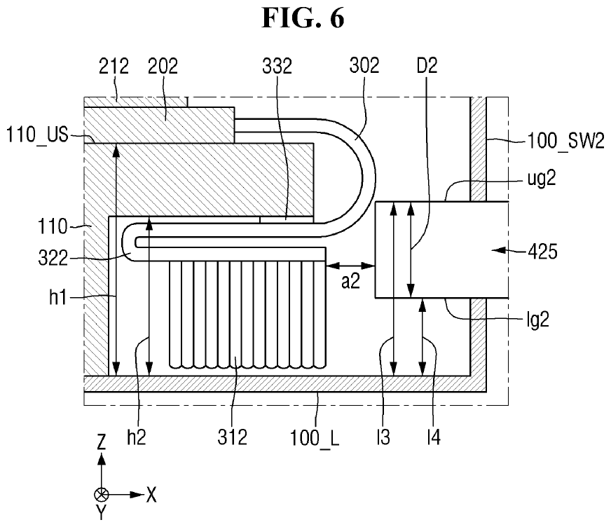

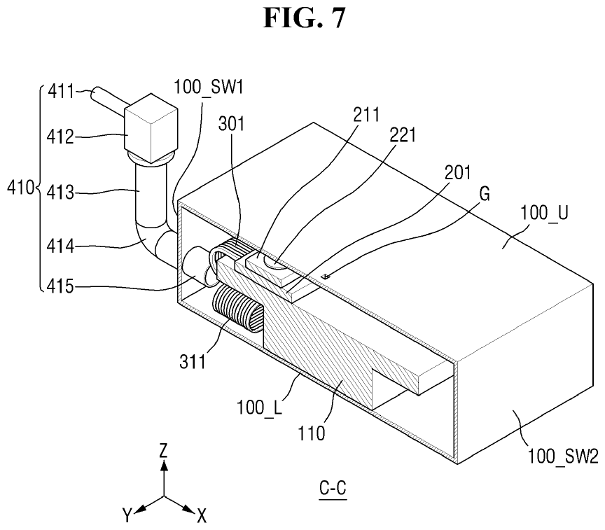

FIG. 2 is a top view of a wafer stage according to one or more embodiments of the present disclosure. FIG. 3 is a cross-sectional view taken along line A-A of FIG. 2 according to one or more embodiments of the present disclosure. FIG. 4 is an enlarged cross-sectional view of a region R1 of FIG. 3 according to one or more embodiments of the present disclosure. FIG. 5 is a cross-sectional view taken along line B-B of FIG. 2 according to one or more embodiments of the present disclosure. FIG. 6 is an enlarged cross-sectional view of a region R2 of FIG. 5 according to one or more embodiments of the present disclosure. FIG. 7 is a perspective view taken along line C-C of FIG. 2 according to one or more embodiments of the present disclosure.

Referring to FIGS. 2 through 7, a wafer stage 100 may include a wafer table 110, position modules, electrostatic chucks, X-cables, Y-cables, operating modules, and exhaust structures. An “X-cable” may refer to a cable that may extend in the X-direction as depicted in the figures and may be configured to move the position module in the X-direction. A “Y-cable” may refer to a cable that may extend in the Y-direction as depicted in the figures and may be configured to move the position module in the Y-direction. The specific reference to “X” and “Y” are meant to correspond to the examples shown in the figures and are used for non-limiting illustrative purposes to aid in describing aspects of example embodiments. It will be understood to one of ordinary skill in the art from the disclosure herein that the X-cables, Y-cables, etc., may not be specifically limited to an “X-direction,” a “Y-direction” etc., as other cable configurations and directions may be implemented without departing from the scope of the example embodiments.

The wafer stage 100 may have a rectangular shape. The wafer stage 100 may also have an empty interior. The wafer stage 100 may serve as a housing surrounding the configuration of the semiconductor manufacturing apparatus.

The wafer stage 100 may include a hole G. The hole G may be formed to penetrate an upper wall 100_U of the wafer stage 100. The hole G may be an empty space. The hole G may have various shapes, such as a slit or circular shape, but the present disclosure is not limited thereto.

The hole G may be positioned along virtual line A-A of FIG. 2. The hole G may be positioned centrally based on the length of the wafer stage 100 in a first direction (e.g., the X direction), but the position of the hole G is not limited thereto.

While only one hole G is illustrated, the present disclosure is not limited thereto. Alternatively, more than one hole may be provided.

Electromagnetic waves may pass through the hole G of the wafer stage 100. The electromagnetic waves that pass through the hole G of the wafer stage 100 may expose wafers to light. The electromagnetic waves may be extreme ultraviolet (EUV), but the present disclosure is not limited thereto.

A blocking mask may be provided to control the electromagnetic waves passing through the hole G. The blocking mask may adjust the degree to which the hole G is covered.

A gas may pass through the hole G of the wafer stage 100. For example, a hydrogen (H₂) gas may pass through the hole G of the wafer stage 100. The gas passing through the hole G may blow away contaminants on the wafers.

The amount of gas passing through the hole G of the wafer stage 100 may be controlled by nozzles. The nozzles may include sensors to detect the amount of gas passing through the wafer stage 100.

The wafer table 110 may support the position modules. Specifically, the position modules may be supported by the wafer table 110 in a third direction (e.g., the Z direction).

The wafer table 110 may be supported by the wafer stage 100. Specifically, the wafer table 110 may be supported by a lower wall 100_L of the wafer stage 100 in the third direction (e.g., the Z direction).

In one or more embodiments, the position modules may have a convex shape in a cross-sectional view taken along an X-Z plane. In other words, the position modules may have an inverted “T” shape in a cross-sectional view taken along the X-Z plane. The position modules may be symmetrical with respect to a Z-Y plane, but the present disclosure is not limited thereto.

The wafer table 110 may include protrusions 112 and a main body 111.

The main body 111 may be supported by the lower wall 100_L of the wafer stage 100. The main body 111 may contact the lower wall 100_L of the wafer stage 100. The main body 111 may have a columnar shape and extend in the third direction (e.g., the Z direction). The main body 111 may have a rectangular shape, but the present disclosure is not limited thereto.

The protrusions 112 may protrude from at least portions of the side walls of the main body 111. The protrusions 112 may extend in the first direction (e.g., the X direction). The protrusions 112 may have a rectangular shape, but the present disclosure is not limited thereto.

In one or more embodiments, the upper surfaces of the protrusions 112 may be on the same plane as the upper surface of the main body 111. When the upper surfaces of the protrusions 112 are coplanar with the upper surface of the main body 111, the position modules may operate smoothly on the wafer table 110. Smooth operation may indicate that the position modules may move with one action, without any obstruction.

The term “same” or “identical” may include not only completely identical but also slightly different, for example, due to process margins or other factors.

In one or more embodiments, the protrusions 112 may protrude from both sidewalls of the main body 111. As the protrusions 112 protrude from both sidewalls of the main body 111, the wafer table 110, which includes the protrusions 112 and the main body 111, may have a “T” shape.

The position modules (e.g., a first position module 201) may be driven on the wafer table 110. Specifically, the position modules may be movable in the first direction (e.g., the X direction) or a second direction (e.g., the Y direction) on an upper surface 110_US of the wafer table 110.

Sidewalls of the position modules may be connected to the X-cables (e.g., X-cable 301). When the X-cables apply external force to the position modules, the X-cables may transmit power to the position modules. The upper surfaces of the position modules may come into contact with the electrostatic chuck.

The electrostatic chucks (e.g., a first electrostatic chuck 211) may be positioned on the position module. The electrostatic chucks may fix the wafers. Specifically, the wafers may be secured to the electrostatic chucks using electrostatic force.

In one or more embodiments, the wafers and the electrostatic chucks may be spaced apart in the third direction (e.g., the Z direction). Gas (e.g., helium (He)) may be supplied between the electrostatic chucks and the wafers. The supplied gas may cool the wafers.

The X-cables (e.g., a first X-cable 301) may drive the position modules in the first direction (e.g., the X direction). The X-cables may contact the position module. The X-cables may rotate around a virtual axis in the second direction (e.g., the Y direction). The X-cables may at least partially wrap around the protrusions 112 of the wafer table 110. The X-cables and the protrusions 112 of the wafer table 110 may not be in contact.

The Y-cables (e.g., a first Y-cable 311) may drive the position modules in the second direction (e.g., the Y direction). The X-cables and the Y-cables may be interconnected. The Y-cables may rotate around a virtual axis in the first direction (e.g., the X direction).

The X-cables (e.g., the first X-cable 301) and the Y-cables (e.g., the first Y-cable 311) may be connected to each other by cable connecting members (e.g., a first cable connecting member 321). The cable connecting members may be integral the X-cables or the Y-cables. The shape of the cable connecting members is not particularly limited as long as they properly connect the X-cables and the Y-cables. The cable connecting members may be flexible. When the X-cables or the Y-cables rotate, the shape of the cable connecting members may change.

The operating modules (e.g., a first operating module 331) may drive the position module through the X-cables (e.g., the first X-cable 301) and the Y-cables (e.g., the first Y-cable 311).

The operating modules may drive the position modules in a desired direction. For example, if the operating modules intend to move the position modules only in the first direction (e.g., the X direction), the position modules may be driven solely in the first direction (e.g., the X direction) and not in the second direction (e.g., the Y direction).

The operating modules may drive the position modules to a desired extent. For example, if the operating modules intend to move the position module only 10 cm in the first direction (e.g., the X direction), the position modules may be driven up to but not exceeding 10 cm in the first direction (e.g., the X direction).

The X-cables and the Y-cables may operate using an infinite track mechanism. Consequently, the X-cables and the Y-cables may continuously move on tracks.

The X-cables and the Y-cables may be flexible. As a result, the X-cables and the Y-cables may be bent. For example, the X-cables may be formed to wrap around at least one or more portions of the protrusions 112.

The exhaust structures (e.g., a first exhaust structure 410) may discharge contaminants within the wafer stage 100 to the outside of the wafer stage 100.

Each of the exhaust structures (e.g., the first exhaust structure 410) may include an exhaust pipe (e.g., a first exhaust pipe 411), a pump (e.g., a first pump 412), a vertical pipe (e.g., a first vertical pipe 413), a connecting pipe (e.g., a first connecting pipe 414), and a penetrating pipe (e.g., a first penetrating pipe 415).

The exhaust pipe may be connected to the pump to discharge the contaminants to the external space. The exhaust pipe may be connected to the pump. The exhaust pipe may have an empty interior.

The pump may move contaminants to the outside of the wafer stage 100 through mechanical energy or electrical energy. The pump may include a turbo pump, a displacement pump, or a specialized pump, but the present disclosure not limited thereto. Each type of pump may be selected based on the type of contaminants to be discharged.

The pump may be connected to the exhaust pipe and the vertical pipe. Contaminants may flow into the pump from the vertical pipe. Contaminants may be discharged from the pump to the exhaust pipe.

The vertical pipe may be connected to the pump. The vertical pipe may extend in the third direction (e.g., the Z direction). The vertical pipe may have an empty interior.

The connecting pipe may connect the vertical pipe and the penetrating pipe. The connecting pipe may have a shape that connects the vertical pipe and the penetrating pipe, and the shape of the connecting pipe is not particularly limited. The connecting pipe may have an empty interior.

The penetrating pipe may pass through the wafer stage 100. The penetrating pipe may have a columnar shape. The penetrating pipe may have an empty interior.

In one or more embodiments, the penetrating pipe may have a cylindrical shape. The penetrating pipe may have a circular shape in a cross-sectional view. The circular cross-section of the penetrating pipe may have a diameter D1. The penetrating pipe is illustrated as having a cylindrical shape, but the shape of the penetrating pipe is not particularly limited.

Each of the exhaust structures have been described as separated into the exhaust pipe, the pump, the vertical pipe, the connecting pipe, and the penetrating pipe, but the present disclosure is not limited thereto. Therefore, each of the exhaust structures may not be physically separated into the exhaust pipe, the pump, the vertical pipe, the connecting pipe, and the penetrating pipe. The exhaust pipe, pump, vertical pipe, connecting pipe, and penetrating pipe may be integrally formed.

The exhaust pipe, the pump, the vertical pipe, the connecting pipe, and the penetrating pipe may not be distinguishable from each other. Additionally, one or more components of the exhaust pipe, the pump, the vertical pipe, the connecting pipe, and the penetrating pipe may be omitted. Furthermore, one or more components may be newly added to the exhaust pipe, the pump, the vertical pipe, the connecting pipe, and the penetrating pipe.

One wafer stage 100 may include two position modules, two electrostatic chucks, two X-cables, two Y-cables, two operating modules, and two exhaust structures. For example, one wafer stage 100 may include the first position module 201, a second position module 202, the first electrostatic chuck 211, a second electrostatic chuck 212, the first X-cable 301, a second X-cable 302, the first Y-cable 311, a second Y-cable 312, the first operating module 331, a second operating module 332, a first exhaust structure 410, and a second exhaust structure 420.

Each pair of components included in one wafer stage 100 may be substantially identical. For example, the first position module 201 may be substantially identical to the second position module 202, the first electrostatic chuck 211 may be substantially identical to the second electrostatic chuck 212, the first X-cable 301 may be substantially identical to the second X-cable 302, the first Y-cable 311 may be substantially identical to the second Y-cable 312, the first operating module 331 may be substantially identical to the second operating module 332, and the first exhaust structure 410 may be substantially identical to the second exhaust structure 420.

Assuming the center of the wafer table 110 is in a X-Y plane, the first position module 201, the first electrostatic chuck 211, the first X-cable 301, the first Y-cable 311, and the first exhaust structure 410 may be respectively symmetrical with the second position module 202, the second electrostatic chuck 212, the second X-cable 302, the second Y-cable 312, and the second exhaust structure 420, with respect to the center of the wafer table 110, but the present disclosure is not limited thereto.

The first exhaust structure 410 may include a first exhaust pipe 411, a first pump 412, a first vertical pipe 413, a first connecting pipe 414, and a first penetrating pipe 415.

The first penetrating pipe 415 may pass through a first sidewall 100_SW1 of the wafer stage 100. The first penetrating pipe 415 may extend in the first direction (e.g., the X direction). The first penetrating pipe 415 may not contact the first X-cable 301. Additionally, the first penetrating pipe 415 may not contact the first Y-cable 311.

In one or more embodiments, the first penetrating pipe 415 may have a cylindrical shape. Thus, the first penetrating pipe 415 may have a circular shape, resulting in a circular cross-sectional view along any plane perpendicular to the first direction (e.g., the X direction). The diameter of the first penetrating pipe 415 may be D1.

The minimum distance in the first direction (e.g., the X direction) from the first Y-cable 311 to the first penetrating pipe 415 may be defined as a first spacing distance a1. The first spacing distance a1 may be equal to or greater than half of the diameter D1.

The second exhaust structure 420 may include a second exhaust pipe 421, a second pump 422, a second vertical pipe 423, a second connecting pipe 424, and a second penetrating pipe 425.

The second penetrating pipe 425 may pass through a second sidewall 100_SW2 of the wafer stage 100. The second penetrating pipe 425 may extend in the first direction (e.g., the X direction). The second penetrating pipe 425 may not be in contact with the second X-cable 302. Additionally, the second penetrating pipe 425 may not be in contact with the second Y-cable 312.

In one or more embodiments, the second penetrating pipe 425 may have a cylindrical shape. Thus, the second penetrating pipe 425 may have a circular shape, resulting in a circular cross-sectional view along any plane perpendicular to the first direction (e.g., the X direction). The diameter of the second penetrating pipe 425 may be D2.

The minimum distance in the first direction (e.g., the X direction) from the second Y-cable 312 to the second penetrating pipe 425 may be defined as a second spacing distance a2. The second spacing distance a2 may be equal to or greater than half of the diameter D2.

Each of the first and second penetrating pipes 415 and 425 may include generator lines. The generator lines may refer to line segments extending along an outer surface of the penetrating pipes to an end of the penetrating pipe, and that are parallel to the central axis of the penetrating pipe (e.g., the central axis of a cylinder). The generator lines with the greatest height from the lower wall 100_L of the wafer stage 100 may be referred to as upper generator lines, and the generator lines with the smallest height from the lower wall 100_L of the wafer stage 100 may be referred to as lower generator lines.

The first penetrating pipe 415 may include generator lines.

A first upper generator line ug1 of the first penetrating pipe 415 may be the generator line with the greatest height from the lower wall 100_L of the wafer stage 100. The first upper generator line ug1 may extend in the first direction (e.g., the X direction). The height from the lower wall 100_L of the wafer stage 100 to the first upper generator line ug1 may be defined as a height 11.

The height 11 may be less than a height h1 from the lower wall 100_L of the wafer stage 100 to the upper surfaces of the protrusions 112.

A first lower generator line lg1 of the first penetrating pipe 415 may be the generator line with the smallest height from the lower wall 100_L of the wafer stage 100. The first lower generator line lg1 may extend in the first direction (e.g., the X direction). The height from the lower wall 100_L of the wafer stage 100 to the first lower generator line lg1 may be defined as a height 12.

The height 12 may be less than a height h2 from the lower wall 100_L of the wafer stage 100 to the bottom surfaces of the protrusions 112.

The distance in the third direction (e.g., the Z direction) between the first upper generator line ug1 and the first lower generator line lg1 may be equal to the diameter of the first penetrating pipe 415. In other words, the distance in the third direction (e.g., the Z direction) between the first upper generator line ug1 and the first lower generator line lg1 may correspond to the diameter D1.

The difference between the heights 12 and 11 may correspond to the diameter of the first penetrating pipe 415. That is, 11−12=D1.

The second penetrating pipe 425 may include generator lines.

A second upper generator line ug2 of the second penetrating pipe 425 may be the generator line with the greatest height from the lower wall 100_L of the wafer stage 100. The second upper generator line ug2 may extend in the first direction (e.g., the X direction). The height from the lower wall 100_L of the wafer stage 100 to the second upper generator line ug2 may be defined as a height 13.

The height 13 may be less than the height h1 from the lower wall 100_L of the wafer stage 100 to the upper surfaces of the protrusions 112.

A second lower generator line lg2 of the second penetrating pipe 425 may be the generator line with the smallest height from the lower wall 100_L of the wafer stage 100. The second lower generator line lg2 may extend in the first direction (e.g., the X direction). The height from the lower wall 100_L of the wafer stage 100 to the second lower generator line lg2 may be defined as a height 14.

The height 14 may be less than the height h2 from the lower wall 100_L of the wafer stage 100 to the bottom surfaces of the protrusions 112.

The distance in the third direction (e.g., the Z direction) between the second upper generator line ug2 and the second lower generator line lg2 may be equal to the diameter of the second penetrating pipe 425. In other words, the distance in the third direction (e.g., the Z direction) between the second upper generator line ug2 and the second lower generator line lg2 may correspond to the diameter D2.

The difference between the heights 14 and 13 may correspond to the diameter of the second penetrating pipe 425. That is, 13−14=D2.

The first wafer 221 may be held in place on the first electrostatic chuck 211. As described above, the first wafer 221 may be patterned by electromagnetic waves passing through the hole G.

The second wafer 222 may be held in place on the second electrostatic chuck 212. As described above, the second wafer 222 may be patterned by electromagnetic waves passing through the hole G.

Referring again to FIGS. 4 and 6, contaminants may be generated at the interface where the first Y-cable 311 and the first cable connecting member 321 contact each other. Additionally, contaminants may be generated at the interface where the second Y-cable 312 and the second cable connecting member 322 contact each other.

To operate the first position module 201, the first Y-cable 311 may rotate about one axis in the first direction (e.g., the X direction). To operate the second position module 202, the second Y-cable 312 may rotate about a different axis in the first direction (e.g., the X direction). When the Y-cables (e.g., the first Y-cable 311) rotate, some contaminants may be generated due to friction between the cable connecting members (e.g., the first cable connecting member 321) and the Y-cables (e.g., the first Y-cable 311). The contaminants may adhere to the wafers, resulting in defects in semiconductor devices.

To remove generated contaminants, the exhaust structures may be utilized. The exhaust structures may draw in contaminants from inside the wafer stage 100 and expel them to the outside of the wafer stage 100. To efficiently draw in contaminants from inside the wafer stage 100, the penetrating pipes of the exhaust structures may be positioned as close as possible to the locations where contaminants are generated. However, the exhaust structures may also lead to defects in the X-cables or Y-cables. To prevent such defects in the X-cables or Y-cables caused by the exhaust structures, the penetrating pipes of the exhaust structures may not contact the X-cables and Y-cables.

When the minimum distance from the Y-cables to the penetrating pipes in the first direction (e.g., the X direction) is equal to or less than half of the diameter of the penetrating pipes, defects in the X-cables or Y-cables may be avoided. Simultaneously, the penetrating pipes may effectively draw in contaminants from inside the wafer stage 100.

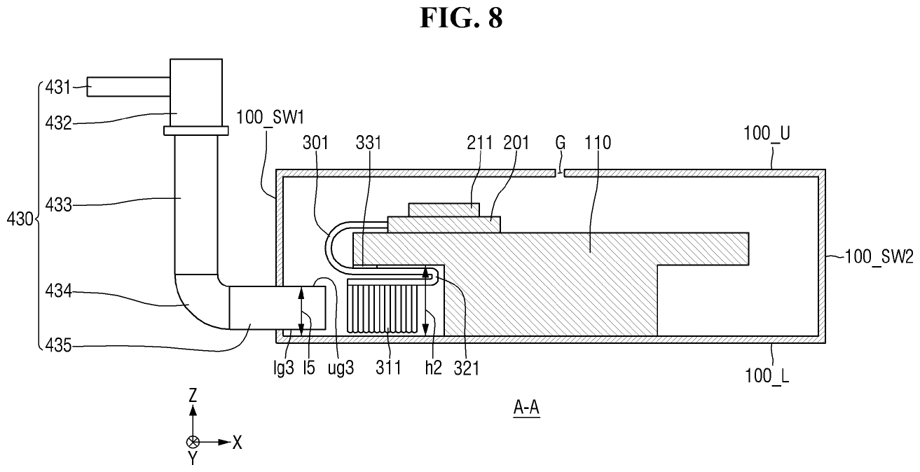

FIG. 8 is a cross-sectional view, taken along line A-A, of a wafer stage according to one or more embodiments of the present disclosure. For convenience, the embodiment of FIG. 8 will hereinafter be described, highlighting the differences with the embodiment of FIGS. 2 through 7.

Referring to FIG. 8, a third exhaust structure 430 may include a third exhaust pipe 431, a third pump 432, a third vertical pipe 433, a third connecting pipe 434, and a third penetrating pipe 435.

The third penetrating pipe 435 may pass through a first sidewall 100_SW1 of a wafer stage 100. The third penetrating pipe 435 may extend in a first direction (e.g., the X direction). The third penetrating pipe 435 may not contact a first X-cable 301 and a first Y-cable 311.

The third penetrating pipe 435 may have a cylindrical shape. Therefore, a cross-sectional view of the third penetrating pipe 435 taken along any plane perpendicular to the first direction (e.g., the X direction) may appear circular.

The third penetrating pipe 435 may include generator lines.

A third upper generator line ug3 of the third penetrating pipe 435 may be the generator line with the greatest height from a lower wall 100_L of the wafer stage 100. The third upper generator line ug3 may extend in the first direction (e.g., the X direction). The height from the lower wall 100_L of the wafer stage 100 to the third upper generator line ug3 may be defined as a height 15.

The height 15 may be less than the height h2 from the lower wall 100_L of the wafer stage 100 to the bottom surfaces of the protrusions 112.

A third lower generator line lg3 of the third penetrating pipe 435 may be the generator line with the smallest height from the lower wall 100_L of the wafer stage 100. The third lower generator line lg3 may extend in the first direction (e.g., the X direction).

The height from the lower wall 100_L of the wafer stage 100 to the third lower generator line lg3 may be less than the height 15 from the lower wall 100_L of the wafer stage 100 to the third upper generator line ug3. In other words, the height of the third lower generator line lg3 relative to the lower wall 100_L of the wafer stage 100 is less than the height of the third upper generator line ug3.

The height from the lower wall 100_L of the wafer stage 100 to the third lower generator line lg3 may be less than the height h2 from the lower wall 100_L of the wafer stage 100 to the bottom surfaces of the protrusions 112.

As the height 15 from the lower wall 100_L of the wafer stage 100 to the third upper generator line ug3 is less than the height h2 from the lower wall 100_L of the wafer stage 100 to the bottom surfaces of the protrusions 112, the third penetrating pipe 435 may draw in a larger amount of contaminants.

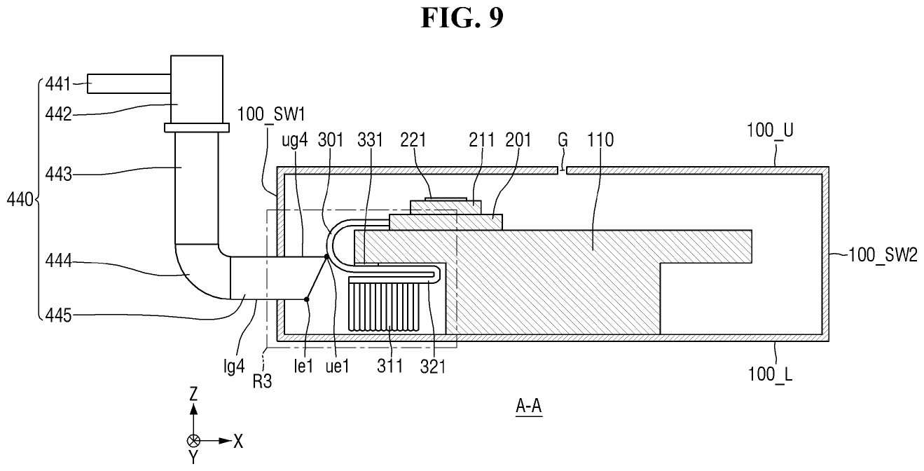

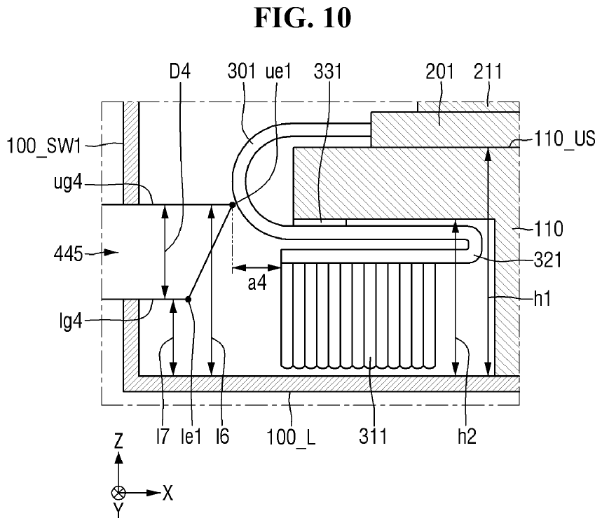

FIG. 9 is a cross-sectional view, taken along line A-A, of a wafer stage according to one or more embodiments of the present disclosure. FIG. 10 is an enlarged cross-sectional view of a region R3 of FIG. 9 according to one or more embodiments of the present disclosure.

Referring to FIGS. 9 and 10, a fourth exhaust structure 440 may include a fourth exhaust pipe 441, a fourth pump 442, a fourth vertical pipe 443, a fourth connecting pipe 444, and a fourth penetrating pipe 445. For convenience, the embodiment of FIGS. 9 and 10 will hereinafter be described, highlighting the differences with the embodiment of FIGS. 2 through 8.

The fourth penetrating pipe 445 may pass through a second sidewall 100_SW2 of a wafer stage 100. The fourth penetrating pipe 445 may extend in the first direction (e.g., the X direction). The fourth penetrating pipe 445 may not contact the first X-cable 301. Additionally, the fourth penetrating pipe 445 may not contact the first Y-cable 311.

The shape of the fourth penetrating pipe 445 may not be cylindrical. Specifically, the fourth penetrating pipe 445 may have a three-dimensional (3D) shape obtained by cutting a cylinder with a plane that forms an acute angle with the X-Y plane. Therefore, the exposed plane of the fourth penetrating pipe 445 may be elliptical in shape.

The fourth penetrating pipe 445 may include generator lines.

A fourth upper generator line ug4 of the fourth penetrating pipe 445 may be the generator line with the greatest height from a lower wall 100_L of the wafer stage 100. The fourth upper generator line ug4 may extend in the first direction (e.g., the X direction). The height from the lower wall 100_L of the wafer stage 100 to the fourth upper generator line ug4 may be defined as a height 16.

A fourth lower generator line lg4 of the fourth penetrating pipe 445 may be the generator line with the smallest height from the lower wall 100_L of the wafer stage 100. The fourth lower generator line lg4 may extend in the first direction (e.g., the X direction). The height from the lower wall 100_L of the wafer stage 100 to the fourth lower generator line lg4 may be defined as a height 17.

The difference between the heights 17 and 16 may correspond to the diameter of the fourth penetrating pipe 445. When cut by a plane perpendicular to the first direction (e.g., the X direction), the fourth penetrating pipe 445 may have a circular cross-sectional view, in which case, the diameter of the fourth penetrating pipe 445 refers to the diameter of the circular cross-sectional view. The diameter of the fourth penetrating pipe 445 may be D4. That is, 16−17=D4.

The length of the fourth upper generator line ug4 in the first direction (e.g., the X direction) and the length of the fourth lower generator line lg4 in the first direction (e.g., the X direction) may be different.

In one or more embodiments, the length of the fourth upper generator line ug4 may be greater than the length of the fourth lower generator line lg4.

The fourth upper generator line ug4 may include a first upper endpoint ue1. The first upper endpoint ue1 may be positioned within the wafer stage 100. The first upper endpoint ue1 may be at the end of the fourth upper generator line ug4.

The fourth lower generator line lg4 may include a first lower endpoint le1. The first lower endpoint le1 may be positioned within the wafer stage 100. The first lower endpoint le1 may be at the end of the fourth lower generator line lg4.

The first upper endpoint ue1 of the fourth upper generator line ug4 and the first lower endpoint le1 of the fourth lower generator line lg4 may not be positioned on any plane perpendicular to the first direction (e.g., the X direction).

Referring to a plane perpendicular to the first direction (e.g., the X direction), passing through the first upper end point, the minimum distance from the corresponding plane to the first Y-cable 311 may be defined as a fourth spacing distance a4. The distance between the fourth upper generator line ug4 and the fourth lower generator line lg4 may be D4. The fourth spacing distance a4 may be equal to or less than half of the distance D4.

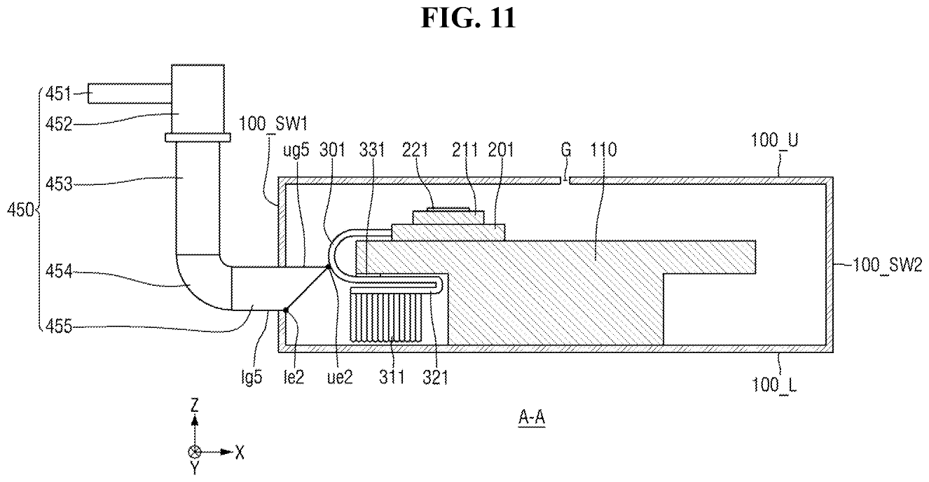

FIG. 11 is a cross-sectional view, taken along line A-A, of a wafer stage according to one or more embodiments of the present disclosure.

Referring to FIG. 11, a fifth exhaust structure 450 may include a fifth exhaust pipe 451, a fifth pump 452, a fifth vertical pipe 453, a fifth connecting pipe 454, and a fifth penetrating pipe 455.

The fifth penetrating pipe 455 may pass through a second sidewall 100_SW2 of a wafer stage 100. The fifth penetrating pipe 455 may extend in a first direction (e.g., the X direction). The fifth penetrating pipe 455 may not contact the first X-cable 301. Additionally, the fifth penetrating pipe 455 may not contact the first Y-cable 311.

The fifth penetrating pipe 455 may not have a cylindrical shape. Specifically, the fifth penetrating pipe 455 may have a 3D shape obtained by cutting a cylinder with a plane that forms an acute angle with the X-Y plane. Therefore, the exposed plane of the fifth penetrating pipe 455 may be elliptical in shape.

The fifth penetrating pipe 455 may include generator lines.

A fifth upper generator line ug5 of the fifth penetrating pipe 455 may be the generator line with the greatest height from a lower wall 100_L of the wafer stage 100. The fifth upper generator line ug5 may extend in the first direction (e.g., the X direction).

A fifth lower generator line lg5 of the fifth penetrating pipe 455 may be the generator line with the smallest height from the lower wall 100_L of the wafer stage 100. The fifth lower generator line lg5 may extend in the first direction (e.g., the X direction).

The length of the fifth upper generator line ug5 in the first direction (e.g., the X direction) and the length of the fifth lower generator line lg5 in the first direction (e.g., the X direction) may be different.

In one or more embodiments, the length of the fifth upper generator line ug5 may be greater than the length of the fifth lower generator line lg5.

The fifth upper generator line ug5 may include a second upper endpoint ue2. The second upper endpoint ue2 may be positioned within the wafer stage 100. The second upper endpoint ue2 may be at the end of the fifth upper generator line ug5.

The fifth lower generator line lg5 may include a second lower endpoint le2. The second lower endpoint le2 may be positioned within the wafer stage 100. The second lower endpoint le2 may be at the end of the fifth lower generator line lg5.

The second lower endpoint le2 may be positioned on one of the sidewalls of the wafer stage 100. For example, the second lower endpoint le2 may be positioned on a first sidewall 100_SW1 of the wafer stage 100.

Specifically, the second lower endpoint le2 may be disposed between the inner side of the first sidewall 100_SW1 of the wafer stage 100 and the outer side of the first sidewall 100_SW1 of the wafer stage 100. Alternatively, the second lower endpoint le2 may be positioned on the inner side of the first sidewall 100_SW1 of the wafer stage 100. Alternatively, the second lower endpoint le2 may be positioned on the outer side of the first sidewall 100_SW1 of the wafer stage 100.

FIG. 11 illustrates that the second lower endpoint le2 be positioned only on the inner side of the first sidewall 100_SW1 of the wafer stage 100, but the present disclosure is not limited thereto.

The term “inner side” may refer to the direction towards the space enclosed by the wafer stage 100. For example, the wafer table 110 may be present on the inner side of the wafer stage 100.

The term “outer side” may refer to the direction towards the space surrounding the wafer stage 100. For example, the pumps may be present on the outer side of the wafer stage 100.

As mentioned earlier, some contaminants may be generated due to friction between cable connecting members and Y-cables. If the generated contaminants move towards the upper wall 100_U of the wafer stage 100, there is a higher possibility of these contaminants being adsorbed onto wafers.

To reduce the likelihood of contaminants moving upwards when the upper generator lines are longer than the lower generator lines and the exposed planes of penetrating pipes are elliptical, the possibility of contaminants being adsorbed onto the wafers may be minimized.

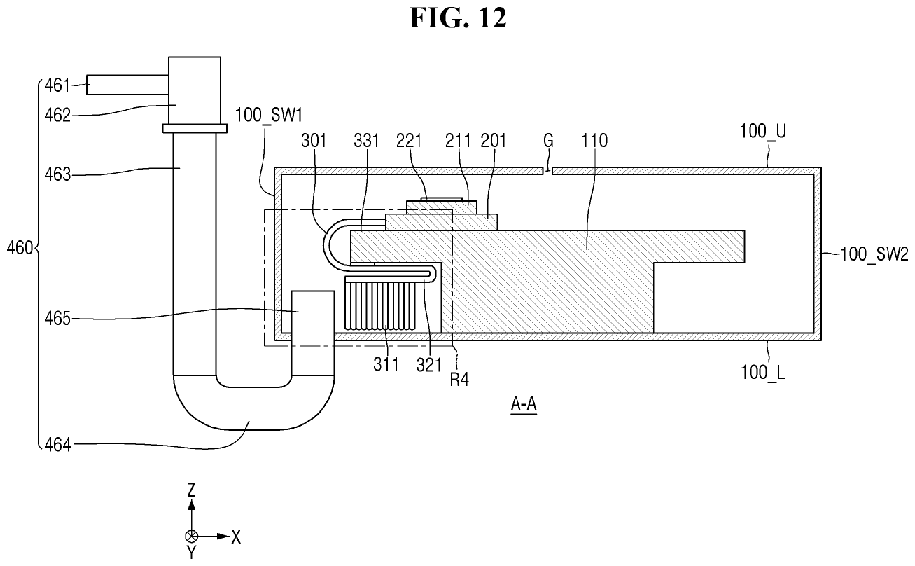

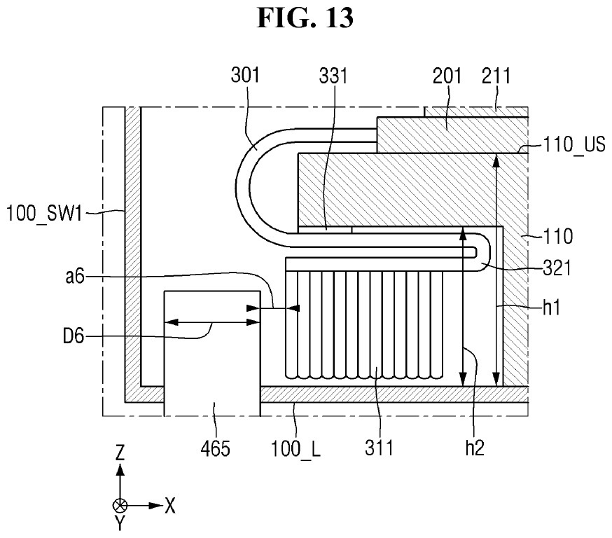

FIG. 12 is a cross-sectional view, taken along line A-A, of a wafer stage according to one or more embodiments of the present disclosure. FIG. 13 is an enlarged cross-sectional view of a region R4 of FIG. 12 according to one or more embodiments of the present disclosure.

Referring to FIGS. 12 and 13, a sixth exhaust structure 460 may include a sixth exhaust pipe 461, a sixth pump 462, a sixth vertical pipe 463, a sixth connecting pipe 464, and a sixth penetrating pipe 465.

The sixth penetrating pipe 465 may pass through a lower wall 100_L of a wafer stage 100. The sixth penetrating pipe 465 may extend in a third direction (e.g., the Z direction). The sixth penetrating pipe 465 may not contact a first X-cable 301. Additionally, the sixth penetrating pipe 465 may not contact a first Y-cable 311.

The sixth penetrating pipe 465 may have a cylindrical shape. Thus, a cross-sectional view of the sixth penetrating pipe 465 when cut by a plane perpendicular to the third direction (e.g., the Z direction) may be circular. The diameter of the sixth penetrating pipe 465 may be D6.

The minimum distance in a first direction (e.g., the X direction) from the first Y-cable 311 to the sixth penetrating pipe 465 may be defined as a sixth spacing distance a6. The sixth spacing distance a6 may be equal to or greater than half of the diameter D6.

As mentioned earlier, one or more contaminants may be generated due to friction between cable connecting members and Y-cables. If the generated contaminants move toward an upper wall 100_U of the wafer stage 100, there is a higher possibility of the contaminants being adsorbed onto wafers.

When the penetrating pipes of exhaust structures pass through the lower wall 100_L of the wafer stage 100, the possibility of contaminants moving upward may be reduced. In other words, if the penetrating pipes of the exhaust structures penetrate through the lower wall 100_L of the wafer stage 100, the possibility of contaminants moving toward the upper wall 100_U of the wafer stage 100 may be lowered. Consequently, the likelihood of contaminants being adsorbed onto the wafers may be minimized.

Each of the embodiments provided in the above description is not excluded from being associated with one or more features of another example or another embodiment also provided herein or not provided herein but consistent with the disclosure

While certain embodiments of the disclosure has been particularly shown and described, it will be understood that various changes in form and details may be made therein without departing from the spirit and scope of the following claims.

What is claimed is:

1. A semiconductor manufacturing apparatus comprising:
a wafer stage;
a wafer table comprising:
a main body supported by the wafer stage; and
a protrusion protruding from a sidewall of the main body in a first direction;
a position module on an upper surface of the wafer table and configured to move in the first direction and a second direction intersecting the first direction;
an electrostatic chuck on an upper surface of the position module;
a first cable connected to the position module, the first cable extending in the first direction and configured to move the position module in the first direction;
a second cable between a bottom surface of the protrusion and a lower wall of the wafer stage, the second cable extending in the second direction and configured to move the position module in the second direction;
a cable connecting member connecting the first cable and the second cable; and
a penetrating pipe extending in the first direction and penetrating a sidewall of the wafer stage,
wherein the penetrating pipe has a circular cross-section along a plane perpendicular to the first direction.

2. The semiconductor manufacturing apparatus of claim 1, further comprising:
a hole in an upper wall of the wafer stage and through which electromagnetic waves generated in a photolithography process pass.

3. The semiconductor manufacturing apparatus of claim 2, wherein the penetrating pipe does not contact the first cable.

4. The semiconductor manufacturing apparatus of claim 1, further comprising:
a pump configured to move contaminants from inside the wafer stage to outside the wafer stage;
a vertical pipe extending in a third direction intersecting the first direction and the second direction; and
a connecting pipe connecting the penetrating pipe and the vertical pipe.

5. The semiconductor manufacturing apparatus of claim 1, wherein, in the first direction, a minimum distance from the second cable to the penetrating pipe is equal to or less than half of a diameter of the penetrating pipe.

6. The semiconductor manufacturing apparatus of claim 1, wherein the penetrating pipe comprises an upper generator line having a first height from the lower wall of the wafer stage that is greatest among heights of generator lines of the penetrating pipe, and
wherein the first height from the lower wall of the wafer stage to the upper generator line is less than a second height from the lower wall of the wafer stage to an upper surface of the protrusion.

7. The semiconductor manufacturing apparatus of claim 1, wherein the penetrating pipe comprises a lower generator line having a third height from the lower wall of the wafer stage that is smallest among heights of generator lines of the penetrating pipe, and
wherein the third height from the lower wall of the wafer stage to the lower generator line is less than a fourth height from the lower wall of the wafer stage to the bottom surface of the protrusion.

8. A semiconductor manufacturing apparatus comprising:
a wafer stage;
a wafer table comprising:
a main body supported by the wafer stage; and
a protrusion protruding from a sidewall of the main body in a first direction;
a position module on an upper surface of the wafer table and configured to move in the first direction and a second direction intersecting the first direction;
an electrostatic chuck on an upper surface of the position module;
a first cable connected to the position module, the first cable extending in the first direction and configured to move the position module in the first direction;
a second cable between a bottom surface of the protrusion and a lower wall of the wafer stage, the second cable extending in the second direction and configured to move the position module in the second direction;
a cable connecting member connecting the first cable and the second cable; and
a penetrating pipe extending in the first direction and penetrating a sidewall of the wafer stage,
wherein the penetrating pipe comprises:
an upper generator line having a first height from the lower wall of the wafer stage that is greatest among heights of generator lines of the penetrating pipe; and
a lower generator line having a second height from the lower wall of the wafer stage that is smallest among the heights of the generator lines of the penetrating pipe, and
wherein a length of the upper generator line in the first direction is different from a length of the lower generator line in the first direction.

9. The semiconductor manufacturing apparatus of claim 8, wherein the upper generator line has a first endpoint within the wafer stage,
wherein the lower generator line has a second endpoint within the wafer stage, and
wherein the first endpoint and the second endpoint are offset in the first direction.

10. The semiconductor manufacturing apparatus of claim 9, wherein the second endpoint is positioned on the sidewall of the wafer stage.

11. The semiconductor manufacturing apparatus of claim 9, wherein a distance from the first endpoint to the second cable is equal to or less than half of a distance between the upper generator line and the lower generator line.

12. The semiconductor manufacturing apparatus of claim 11, wherein the penetrating pipe does not contact the first cable.

13. The semiconductor manufacturing apparatus of claim 8, further comprising:
a hole in an upper wall of the wafer stage and through which electromagnetic waves generated in a photolithography process pass.

14. The semiconductor manufacturing apparatus of claim 8, further comprising:
a pump configured to move contaminants from inside the wafer stage to outside the wafer stage;
a vertical pipe extending in a third direction intersecting the first direction and the second direction; and
a connecting pipe connecting the penetrating pipe and the vertical pipe.

15. The semiconductor manufacturing apparatus of claim 8, wherein a third height from the lower wall of the wafer stage to the upper generator line is less than a fourth height from the lower wall of the wafer stage to an upper surface of the protrusion.

16. The semiconductor manufacturing apparatus of claim 8, wherein a third height from the lower wall of the wafer stage to the lower generator line is less than a fourth height from the lower wall of the wafer stage to the bottom surface of the protrusion.

17. A semiconductor manufacturing apparatus, comprising:
a wafer stage;
a wafer table comprising:
a main body supported by the wafer stage; and
a protrusion protruding from a sidewall of the main body in a first direction;
a position module on an upper surface of the wafer table and configured to move in the first direction and a second direction intersecting the first direction;
an electrostatic chuck on an upper surface of the position module;
a first cable connected to the position module, the first cable extending in the first direction and configured to move the position module in the first direction;
a second cable between a bottom surface of the protrusion and a lower wall of the wafer stage, the second cable extending in the second direction and configured to move the position module in the second direction;
a cable connecting member connecting the first cable and the second cable; and
a penetrating pipe extending in a third direction intersecting the first direction and the second direction, the penetrating pipe penetrating the lower wall of the wafer stage,
wherein the penetrating pipe has a circular cross-section along a plane perpendicular to the third direction.

18. The semiconductor manufacturing apparatus of claim 17, wherein, in the first direction, a minimum distance from the second cable to the penetrating pipe is equal to or less than half of a diameter of the penetrating pipe.

19. The semiconductor manufacturing apparatus of claim 18, wherein the penetrating pipe does not contact the second cable.

20. The semiconductor manufacturing apparatus of claim 17, wherein a first height from the lower wall of the wafer stage to an uppermost portion of the penetrating pipe is less than a second height from the lower wall of the wafer stage to an upper surface of the protrusion.
